(19) United States
(12) Patent Application Publication
(10) Pub. No.: US 2024/0019128 A1
(43) Pub. Date: Jan. 18, 2024

(54) METHOD FOR OPERATING A COOKTOP AND COOKTOP CONFIGURED TO CARRY OUT THIS METHOD

(71) Applicant: E.G.O. Elektro-Gerätebau GmbH, Oberderdingen (DE)

(72) Inventors: Sandra Gaessler, Vaihingen an der Enz (DE); Peter Walk, Karlsruhe (DE)

(21) Appl. No.: 18/340,109

(22) Filed: Jun. 23, 2023

(30) Foreign Application Priority Data
Jul. 12, 2022 (DE) 10 2022 207 122.0

(51) Int. Cl. F24C 7/08

(52) U.S. Cl. CPC F24C 7/086; F24C 7/083

(57) ABSTRACT

A cooktop with an operating means with operating elements with capacitive sensor elements has a control means which is configured to provide a wipe protection function which is activatable and deactivatable by an operator. Said function ensures that, after the activation thereof, sensor signals from the sensor element means are not converted into operating commands by the operating means. The wipe protection function is only automatically deactivated again by the operating means if, after the activation thereof, a predetermined waiting period of 0 sec to 20 sec has elapsed since the last detection of an operation on at least one of the sensor element means or since the last receipt of a sensor signal from at least one of the sensor element means without renewed detection of operation or receipt of a sensor signal.

### CROSS-REFERENCE TO RELATED APPLICATIONS

This application claims priority to German Application No. 10 2022 207 122.0, filed Jul. 12, 2022, the contents of which are hereby incorporated herein in its entirety by reference.

### FIELD OF APPLICATION AND PRIOR ART

The invention relates to a method for operating a cooktop and to a cooktop configured to carry out this method.

DE 102010062745 A1 discloses a “wipe protection” function for a cooktop. This serves to deactivate operating elements of a cooktop operating means for a certain period of time such that any liquid food which is being cooked and has overflowed causes no disruption during this time, or that the surface of the cooktop above the operating element can be cleaned with a damp cloth. In operating elements which have a capacitive principle of operation such as for example according to EP 859467 A1 and EP 859468 A1, a film of liquid or moisture over the operating element has a disruptive effect because said film cannot always necessarily be clearly distinguished from desired operation with a finger. Activation of the wipe protection function by way of an operating element provided for this purpose has the effect, as it were, of deactivating the operating elements of the operating means. If optionally so configured, the wipe protection function can either be purposefully manually canceled or deactivated by the operator, i.e. by operating the operating element provided for this purpose again, or the wipe protection function is automatically deactivated after a predefined time. In the former case, renewed operation by the operator is required. In the second case, the time of deactivation of the wipe protection function may be inappropriate and hinder the operator in operation or result in errors if a wiping operation is still under way.

### Problem and Solution

The object of the present invention is to provide a method as stated above for operating a cooktop and a cooktop configured to carry out this method, with which prior art problems can be solved and which in particular makes it possible to be able to operate and use a cooktop in a safe and practical manner with the greatest possible operating safety and the greatest possible user convenience.

Said object is achieved by a method having the features of claim 1 and by a cooktop having the features of claim 16. Advantageous and preferred developments of the invention are the subject of the additional claims and are explained in more detail below. Some of the features are described only for the method or only for the cooktop. They are, however, intended to apply by themselves and independently of one another both to a method and to a cooktop. The wording of the claims forms part of the content of the description by explicit reference.

In the method for operating a cooktop, the cooktop has a cooktop plate, heating means on the cooktop plate and an operating means on or below the cooktop plate. The operating means has a plurality of sensor element means under the cooktop plate in order to detect the presence of a finger for operation on the upper side of the cooktop plate above one of the sensor element means, wherein the sensor element means advantageously have capacitive sensor elements for the operating elements. The sensor element means are also configured to detect operation and optionally also the presence of liquid on the upper side of the cooktop plate above a sensor element means. On the basis of this detection, sensor signals can be generated, wherein a control means cooperating therewith is also provided for this purpose. Advantageously, it is the control means of the operating means itself. Detection of liquid above a sensor element means is then possible if a plurality of adjacent sensor elements simultaneously generate sensor signals as if they had been operated, i.e. when they are deemed to have been simultaneously operated.

According to the invention, the operating means has a wipe protection function which is activatable by an operator and deactivates itself automatically, and can possibly also be deactivated on the operating means itself. The wipe protection function is configured such that, after activation of the wipe protection function, sensor signals from the sensor element means or corresponding operating elements are not converted into operating commands by the operating means or do not bring about operation, i.e. they are effectively blocked or ignored. The wipe protection function is only automatically deactivated again by the operating means if, after activation of the wipe protection function, a predetermined waiting period of 0 sec or 0.1 sec to 20 sec has elapsed since the last detection of an operation on at least one of the sensor element means or since the last receipt of a sensor signal from at least one of the sensor element means which indicates that a finger or liquid has been detected on the upper side of the cooktop plate above one of the sensor element means without renewed operation or receipt of a sensor signal from precisely this sensor element means or any other sensor element means having been detected. The waiting period may advantageously last 1 sec to 5 sec or up to 10 sec. It can possibly also be modified by an operator, for example in a specific settings menu. If an operation or receipt of a sensor signal is detected in this manner within the waiting period or before it elapses, the wipe protection function is reactivated again and the waiting period starts to run again as soon as no operation or receipt of a sensor signal has been detected again. If no sensor element activity is identified after activation of the wipe protection function, the wipe protection function is nevertheless deactivated after a preset timeout period so that the operator does not have to wait for an inconveniently long period after unintentional activation on subsequent operation. The timer after detected sensor element activity and the timeout timer if no sensor signal at all is detected may be identical but may also be different.

In this way, a kind of automated or self-effected end to the wipe protection function can be brought about when it is actually no longer needed. The operator then no longer necessarily has to terminate it. The stated waiting period can possibly be generally modified by an operator in a basic menu setting of the cooktop or control means. This may in particular be in a direction or a waiting period which the operator considers practical and desirable based on their own experience.

In one possible development of the invention, the wipe protection function can apply to all the sensor element means of the control device except for one sensor element means for an on/off function of the cooktop in such a manner that an operation on this sensor element means always results in the cooktop being switched on or off. This preferably occurs irrespective of whether it has been operated alone or simultaneously with further sensor element means, or whether sensor signals have been received from further sensor element means. In one possible further development of the invention, an operating element or a switch for activating and/or deactivating the wipe protection function may itself also be excluded from the wipe protection function. In this way, an operator can, as it were, always deactivate the wipe protection function.

In one advantageous development of the invention, it is possible for activation of the wipe protection function to be signaled by the operating means, in particular acoustically and/or visually, regardless of how it has been activated. The signal is particularly advantageously provided both acoustically and visually, for example by a flashing display and a loud beep or buzzing sound. Similarly or identically, deactivation of the wipe protection function may be signaled by the operating means, in particular acoustically and/or visually. This preferably proceeds in the same manner as on activation of the wipe protection function.

A first possible development of the invention may provide that the wipe protection function can be activated or is activatable by operating a single sensor element means or a single operating element. Activation is very quick and easy to carry out in this case. Correspondingly, the wipe protection function can also be deactivated by operating a single sensor element means, advantageously if this sensor element means is excepted from the wipe protection function. Said means is otherwise not available for deactivation.

A second possible development of the invention may provide that the wipe protection function can be activated or is activatable by simultaneous operation of precisely two or at least two sensor element means or operating elements; alternatively the two sensor element means must be operated in quick succession. The precisely two or at least two sensor element means or operating elements are advantageously then arranged spatially close to one another, in particular adjacent to one another in one or two directions. Here, too, the wipe protection function can be correspondingly deactivated by simultaneous operation of precisely two or at least two sensor element means.

A further possible development of the invention may provide that, after a time, which may be from 2 sec to 2 min and preferably from 5 sec to 20 sec, has elapsed after activation of the wipe protection function without detection of an operation on at least one sensor element means or receipt of a sensor signal from at least one sensor element means, which might indicate detection of operation or water thereover, the wipe protection function is automatically deactivated by the operating means. It may preferably be provided that no operation or receipt of a signal has occurred at at least two sensor element means and not at just one single sensor element means. This can further increase safety.

In a preferred further development of the invention, the wipe protection function remains active only if, within the above-stated waiting period after the activation thereof, not only one sensor element means, but at least two sensor element means are operated or sensor signals are received from at least two sensor element means, in particular simultaneously. Similarly to the above description, this increases safety or ensures that an procedure corresponding to or brought about by wiping with a damp cloth or the presence of liquid on the cooktop plate can be detected, in particular can be distinguished from a normal operation on a single sensor element means or on a single operating element.

The cooktop according to the invention has a cooktop plate, heating means thereon and an operating means on or under the cooktop plate. A control means, advantageously a controller or microcontroller, is provided in the operating means. The control means can thus drive and evaluate the sensor element means. A signaling means, which in particular generates acoustic signals, can advantageously also be provided in the operating means. A visual display is advantageously also provided.

The sensor element means of the operating elements may be configured, optionally together with the control means and additional sensors, to detect operation by means of a finger and the presence of liquid on the upper side of the cooktop plate above a sensor element means. They then generate sensor signals which are detected and evaluated in the operating means or by the above-stated control means. In particular if the wipe protection function is not activated, operating commands are generated from the sensor signals, and said commands are them implemented by the operating means or the control means on the cooktop, in particular with regard to a heating power at one of the rings.

These and other features emerge from the description and the drawings, in addition to the claims, wherein the individual features can be realized in themselves either alone or severally in the form of sub-combinations in one embodiment of the invention and in other areas, and can constitute advantageous embodiments eligible for protection in themselves, for which protection is sought here. The subdivision of the application into individual sections and sub-headings does not limit the statements made thereunder in their general validity.

### BRIEF DESCRIPTION OF THE DRAWINGS

Further advantages and aspects of the invention can be found in the claims and in the description of exemplary embodiments of the invention that are explained in the following on the basis of the figures, in which:

FIG. 1 shows a plan view of a cooktop according to the invention with rings in a cooking zone and an operating means in an operating zone,

FIG. 2 shows the cooktop of FIG. 1 with a pan set down at the front left, from which overflowing cooking water has escaped onto operating elements of the operating means,

FIG. 3 shows a situation similar to FIG. 2, in which a damp cloth is being used to wipe in the area of the escaping cooking water,

FIG. 4 shows the state after wiping with a damp cloth according to FIG. 3, in which a damp area remains above some operating elements, and

FIG. 5 shows a state shortly after that of FIG. 4, in which the damp area has either completely disappeared or still remains over the operating element on the far left.

### DETAILED DESCRIPTION OF THE EXEMPLARY EMBODIMENTS

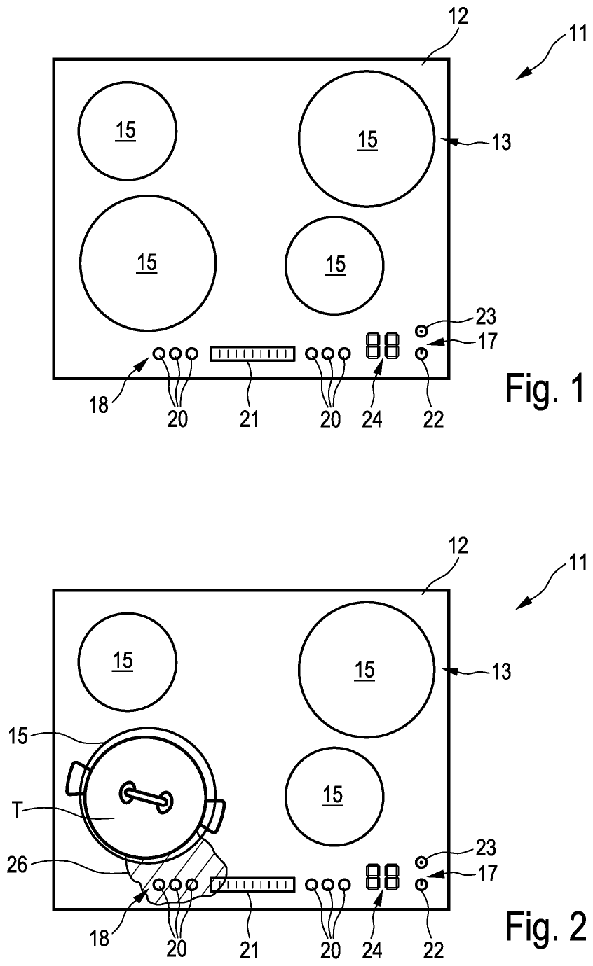

FIG. 1 shows a cooktop 11 with a cooktop plate 12. In the rear and larger zone of the cooktop plate 12, a cooking zone 13 with four rings 15 is provided which can be heated, for example, by means of induction heating coils arranged under the cooktop plate 12. The front zone of the cooktop 11 forms an operating zone 17, in which an operating means 18 is arranged. The operating means 18 has a plurality of round operating elements 20, a central elongate slider 21 and an on/off switch 22. To the left of the latter, a display 24 is arranged, for example as a two-digit seven-segment display. A wipe protection switch 23 is furthermore provided as one of the operating elements. All these operating elements are formed by sensor element means in the form of capacitive sensor elements under the cooktop plate 12, as are known from the prior art mentioned at the beginning. The operating means 18 has a control means (not shown), advantageously in the form of a microcontroller, in which sensor signals from capacitive sensor elements of the operating elements are evaluated, both in themselves and also in connection with neighboring operating elements. The operating means 18 or the control means thereof can accordingly detect whether an operating error has occurred, for example whether a number of operating elements are being operated simultaneously in a manner which is, however, not intended. Furthermore, as will be addressed in greater detail below and has already been described above, it is possible to detect liquid or water, or alternatively for example also a damp cloth, on top of the cooktop plate 12 above the operating means 18 or the operating elements 20 to 23.

FIG. 2 shows how a pan T is positioned on the front left ring 15 from which cooking water 26 has escaped while for example pasta is being cooked and has spread as a puddle of water on the surface of the cooktop plate 12. As is shown, the film of water formed by the cooking water 26 is covering the three operating elements 20 on the left beside the slider 21 and is also partially covering the latter. Furthermore, another zone of the cooktop plate 12 in the cooking zone 13 can also be covered by the cooking water 26 but where it does not interfere, at least not with operation or the operating means 18.

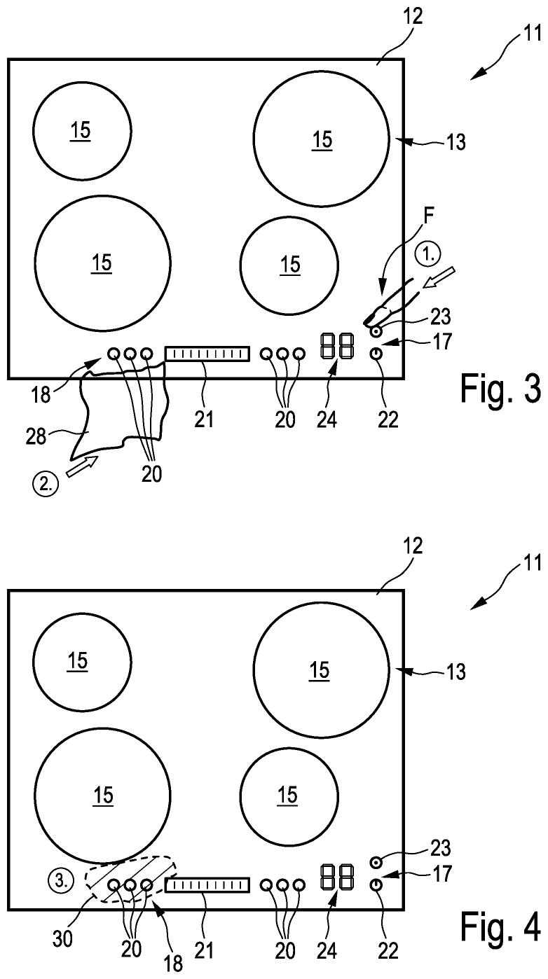

In an advantageous development of the invention, the control means of the operating means 18 can already detect such cooking water 26 as such and not as an operation with an applied finger F, as shown in FIG. 3. In any event, the control means with the operating means 18 and together with the operating elements 20 or the capacitive sensor elements thereof can detect when the cooking water 26 is present over one or over at least two operating elements 20 to 23. In this case, the latter are, as it were, to a certain extent capacitively coupled to each other by the electrically conductive cooking water 26. Such detection is evaluated as a fault scenario and operating commands corresponding to the covered operating elements are then, for example, also blocked. In addition, a visual and/or acoustic signal, for example flashing on the display 24 or a loud beeping, can optionally be generated.

FIG. 2 thus shows a possible case of how at least one operating element 20, advantageously more than one, can be covered by water or liquid in general, which has been caused unintentionally. This situation, or what can then be done in a method according to the invention, will be discussed in greater detail later.

A somewhat different situation is shown in FIG. 3, in which no cooking water or other liquid has unintentionally reached the upper side of the cooktop plate 12 in the region of the operating means 18 or the operating elements 20 to 23. In this exemplary case, an operator would like to wipe the upper side of the cooktop plate 12 with a damp cloth, in particular for cleaning. To this end, in a first step, the operator actuates the wipe protection switch 23 or the corresponding operating element with a finger F. This is only possible when the cooktop 11 is switched on, but it is after all only in this case that there is a need for such a wipe protection function. Either directly after activation of the wipe protection function, it can be checked whether it is possible to detect by way of operating elements 20 to 23, whether a damp cloth and thus liquid per se is present above at least two of the operating elements 20 to 23 or above at least one of the operating elements. To this end, a certain holding period, for example up to 5 sec, during which the wipe protection function remains activated even if nothing is detected on the operating elements or the sensor element means thereof, may advantageously be provided. This has the advantage that the operator need not begin to wipe with the damp cloth 28 above the operating elements 20 to 23 in order to clean the cooktop plate 12 immediately and directly after activation of the wipe protection function. This makes the process more practical. If nothing were then identified within 5 sec, the wipe protection function would be deactivated again purely on this basis. The above-stated waiting period actually only begins once the wipe protection function has been activated, if an operation has been detected on one of the operating elements or the sensor element means thereof or if a sensor signal has been received therefrom.

This is because, if the operator then starts to clean the cooktop plate 12 with the damp cloth 28 which produces a film of moisture on top of the cooktop plate 12, this is permanently detected on at least one or more of operating elements 20 to 23. The operating means 18 or the control means thereof thus assumes that wiping is still being carried out with the damp cloth 28 and the wipe protection function naturally remains activated for this time, it being obvious that these sensor signals do not originate from operation.

On consideration of the cases of FIGS. 2 and 3, in the case of FIG. 2, an operator can therefore still actuate the wipe protection function at the wipe protection switch 23 according to FIG. 3 even directly after identifying the escape of cooking water 26 over operating elements. Then, also on the basis of the identified fault scenario due to the cooking water 26, the operating means 18 can ignore this cooking water 26 or the signals generated thereby on the operating elements or the sensor element means thereof. The operator can thus, for example, deactivate the visual and/or acoustic signaling of the escaped cooking water 26, since this is frequently perceived as annoying. Furthermore, this case is conventionally followed by the removal of the cooking water 26 with a cloth 28 shown in FIG. 3.

FIG. 4 shows how, as it were, in a third step a damp area 30 or film of water, outlined in dashed lines, is still present as a result of wiping with the damp cloth 28 as substantially removed cooking water 26 or other moisture. The wipe protection function thus remains activated.

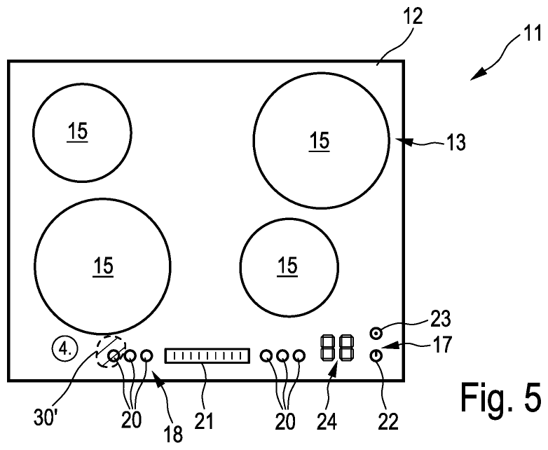

In a fourth step corresponding to FIG. 5, the film of water of the still somewhat larger damp area 30 of FIG. 4 has become smaller and now only still covers the operating element 30 on the far left as the damp area 30′, which is again shown dashed. One development of the invention can now here provide that the control means of the operating means 18 allows the waiting period to elapse if fewer than two operating elements are still being operated or can identify liquid above themselves. In this case, the waiting period can begin to elapse and, depending on the setting thereof, for example to 5 sec, the wipe protection function can be deactivated once said 5 sec have elapsed. Normal operation on the operating means 18 is then possible again.

Another development of the invention may provide that the waiting period begins to elapse when, with the wipe protection function activated, no operating element at all is any longer being operated or no liquid can any longer be identified over any operating element. This is then a still stricter distinction and, in the case shown in FIG. 5, the waiting period would not yet start to elapse. For this to happen, even the final damp area 30′ over the operating element 20 would have to no longer be present.

If, once the waiting period has started to run, for example after 3 sec if the waiting period is 5 sec, operation or liquid on at least one operating element or on at least two operating elements is identified, the wipe protection function is considered to be reactivated or it remains activated. All operations except for on the on/off switch 22, and optionally also on the wipe protection switch 23, are ignored. Only when operation or liquid is again no longer detected over fewer than two operating elements, or possibly over no operating element, does the waiting period begin to run again. If the period then elapses, for example after the above-stated predetermined 5 sec, the wipe protection function is deactivated.

It is accordingly possible to achieve automatic deactivation of the wipe protection function as soon as it is, according to its definition, no longer necessary. To be on the safe side, the waiting period provided may be zero or very short, but may also be up to 20 sec.

In a still further development of the invention, it is conceivable for the operating element of the wipe protection switch 23 as well as of the on/off switch 22 not to be deactivated by the wipe protection function. Accordingly, on the one hand, it may be provided as described above that the wipe protection function be automatically deactivated under specific conditions. Furthermore, however, it is then also possible for it in addition to be manually deactivated at any time by an operator, for example because it is no longer necessary in the operator's opinion.

It is readily conceivable that, instead of the wipe protection switch 23 being actuated as a single switch with one finger F according to FIG. 3, two or more operating elements or switches have to be actuated simultaneously or in quick succession. It may then also be possible to dispense with such a separate operating element and so reduce structural complexity.

It may moreover be provided that an above-stated holding period is not implemented but instead that, after activation of the wipe protection function, no liquid and no operation is detected within a short period on an operating element or the sensor element means thereof. It may accordingly be provided that, after a time of between 5 sec and 20 sec after activation of the wipe protection function, if absolutely nothing is detected, the wipe protection function is automatically deactivated by the operating means. It this case, said function was obviously not necessary, either because no wiping was performed at all or at least not above the operating means 18 or the operating elements 20 to 23 thereof.

1. A method for operating a cooktop, wherein said cooktop comprises:
a cooktop plate,
heating means on said cooktop plate,
an operating means on or below said cooktop plate, wherein said operating means has a plurality of sensor element means under said cooktop plate in order to detect a presence of a finger for operation on an upper side of said cooktop plate above one of said sensor element means, wherein said sensor element means are also configured to detect a presence of liquid on said upper side of said cooktop plate above at least one said sensor element means and to generate sensor signals,
wherein
said operating means has a wipe protection function which is activatable and deactivatable by an operator,
said wipe protection function is configured such that, after activation of said wipe protection function, sensor signals from said sensor element means are not converted into operating commands by said operating means or do not bring about operation,
said wipe protection function is only automatically deactivated again by said operating means if, after activation of said wipe protection function, a predetermined waiting period of 0 sec to 20 sec has elapsed since a last detection of an operation on at least one of said sensor element means or since a last receipt of a sensor signal from at least one of said sensor element means which indicates that a finger or liquid has been detected on said upper side of said cooktop plate above one of said sensor element means without a renewed detection of operation or a receipt of a sensor signal.

2. The method as claimed in claim 1, wherein said predetermined waiting period is 1 sec to 5 sec.

3. The method as claimed in claim 1, wherein said wipe protection function applies to all said sensor element means of said control device except for one sensor element means for an on/off function of said cooktop in such a manner that an operation on said sensor element means always results in said cooktop being switched on or off.

4. The method as claimed in claim 3, wherein said wipe protection function applies to all said sensor element means of said control device except for one sensor element means for an on/off function of said cooktop in such a manner that an operation on said sensor element means always results in said cooktop being switched on or off irrespective of whether said sensor element means has been operated alone or simultaneously with further sensor element means or whether sensor signals have been received from further sensor element means.

5. The method as claimed in claim 1, wherein activation of said wipe protection function is signaled by said operating means.

6. The method as claimed in claim 1, wherein deactivation of said wipe protection function is signaled by said operating means.

7. The method as claimed in claim 5, wherein activation of said wipe protection function or deactivation of said wipe protection function is signaled by said operating means acoustically and/or visually.

8. The method as claimed in claim 6, wherein deactivation of said wipe protection function is signaled by said operating means in the same manner as on activation of said wipe protection function.

9. The method as claimed in claim 1, wherein said wipe protection function is activated by operation of a single said sensor element means.

10. The method as claimed in claim 1, wherein said wipe protection function is activated by simultaneous operation of at least two said sensor element means.

11. The method as claimed in claim 1, wherein said wipe protection function is deactivatable by an operator on said operating means in the same manner as said wipe protection function is activatable.

12. The method as claimed in claim 1, wherein after 2 min to 20 min after activation of said wipe protection function without detection of an operation on at least one said sensor element means or receipt of a sensor signal from at least one said sensor element means with regard to a detection of water thereover, said wipe protection function is automatically deactivated by said operating means.

13. The method as claimed in claim 1, wherein after 2 min to 20 min after activation of said wipe protection function without detection of an operation on at least two said sensor element means or receipt of a sensor signal from at least two said sensor element means with regard to a detection of water thereover, said wipe protection function is automatically deactivated by said operating means.

14. The method as claimed in claim 1, wherein said wipe protection function remains active only if, after an activation thereof, at least two said sensor element means are operated or sensor signals from at least two said sensor element means are received within said predetermined waiting period.

15. The method as claimed in claim 1, wherein said wipe protection function remains active only if, after an activation thereof, at least two said sensor element means are operated or sensor signals from at least two said sensor element means are received simultaneously within said predetermined waiting period.

16. A cooktop with:
a cooktop plate,
heating means on said cooktop plate,
an operating means on or below said cooktop plate, wherein said operating means has a plurality of sensor element means under said cooktop plate in order to detect a presence of a finger for operation on said upper side of said cooktop plate above one of said sensor element means, a control means in said operating means which is configured to drive and evaluate said sensor element means,
wherein said sensor element means are configured to detect operation by means of a finger on said upper side of said cooktop plate above one said sensor element means and to generate sensor signals for carrying out said method as claimed in claim 1.

17. The cooktop as claimed in claim 16, wherein said:
sensor element means are configured, together with said control means and additional sensors, to detect operation by means of a finger and a presence of liquid on said upper side of said cooktop plate above one said sensor element means, and
said operating means has a wipe protection function which is activatable and deactivatable by an operator,
said wipe protection function is configured such that, after activation of said wipe protection function, sensor signals from said sensor element means are not converted into operating commands by said operating means or do not bring about operation, and
said wipe protection function is only automatically deactivated again by said operating means if, after activation of said wipe protection function, a predetermined waiting period of 0 sec to 20 sec has elapsed since a last detection of an operation on at least one of said sensor element means or since a last receipt of a sensor signal from at least one of said sensor element means which indicates that a finger or liquid has been detected on said upper side of said cooktop plate above one of said sensor element means without a renewed detection of operation or a receipt of a sensor signal.

18. The cooktop as claimed in claim 16, wherein said cooktop has a signaling means in said operating means.

19. The cooktop as claimed in claim 16, wherein said cooktop has a control means in said operating means which drives and evaluates said sensor element means.
